(19) United States
(12) Patent Application Publication
(10) Pub. No.: US 2006/0118043 A1
(43) Pub. Date: Jun. 8, 2006

(54) Method for producing coated workpieces, uses and installation for the method

(76) Inventors: Rudolf Wagner, Fontnas (CH); Siegfried Wiltsche, Feldkirch (AT); Juergen Ramm, Sevelen (CH)

Correspondence Address: CROWELL & MORING LLP;INTELLECTUAL PROPERTY GROUP, P.O. BOX 14300, WASHINGTON, DC, 20044-4300, US

(21) Appl. No.: 11/271,738

(22) Filed: Nov. 14, 2005

Related U.S. Application Data
(63) Continuation of application No. 09/792,055, filed on Feb. 26, 2001, now abandoned.

(51) Int. Cl. C23C 16/00

(52) U.S. Cl. 118/723 E

(57) ABSTRACT

A method of manufacturing electronic or opto-electronic or micromechanic components by providing a vacuum where the external surface of a wall is exposed to ambient air and the inner surface enclosed as a processing area. A base body of a part to be manufactured is introduced into the processing area and a low energy plasma discharged is generated in the process area, the ion energy at the surface of the base body is between 0 and 15 eV in order to introduce a reactive gas. Subsequently, the reactive gas treats the base body in order to separate the processing area from an inner surface of the wall and enclosing the processing area during the treatment.

### BACKGROUND AND SUMMARY OF THE INVENTION

International Patent Document WO98/58099 is attached to this specification as a description of the process.

The present invention relates to a process for producing parts as electronic, opto-electronic, optical or micromechanical components or as intermediate products therefor by using at least one plasma-enhanced treatment step, in which reactive gas or reactive gas mixture admitted to a process space is activated by means of a low-energy plasma discharge with ion energy E on the surface of the part of
0 eV<E<15 eV

Furthermore, the invention relates to a process for producing a virtual substrate or a component thereof, preferably on a silicon germanium base, comprising at least one cleaning step, according to the preamble of Claim 28. In addition, the invention relates to vacuum treatment systems.

The present invention basically relates to the production of parts for which the same demands are to be made as during the coating of parts with an epitaxial layer.

From International Patent Document WO98/58099 (enclosed) by the same applicant, processes as well as systems of the initially mentioned type are known. As a plasma-enhanced treatment step, in which reactive gas or reactive gas mixture admitted to a process space is activated by means of a low-energy plasma discharge with ions of the ion energy E on the surface of the part of
0 eV<E<15 eV,
is described in detail and only the coating of a workpiece of a quality sufficient for the epitaxy is described and claimed there. The plasma generated by the low-energy plasma discharge is essentially composed of electrons, single and multiple charged ions and neutral particles (atoms, dissociated molecules) as well as excited but non-ionized neutral particles. The energy range
0 eV<E<15 eV
of the single ionized ions is characteristic of the plasma described herein. 15 eV represents the so-called sputtering threshold, above which, when the ions act upon the substrate, damage may occur there. Even up to 100 eV, electrons contribute essentially only to the heating of the substrate. It is also known that, particularly in the case of the DC low voltage plasma generating arrangement particularly preferred in this case—as will be explained in the following the above-mentioned energy range of the single-charged ions simultaneously limits in the upward direction the energy range of the neutral particles existing in the plasma as well as excited neutral particles. The reason is that the neutral particles obtain their significant energy contribution by impacts with the ions.

Also, a vacuum treatment system for the above-mentioned coating is explained in detail in International Patent Document WO98/58099 and has a vacuum chamber, a workpiece carrier in the vacuum chamber, a plasma generating arrangement for generating a plasma in the chamber as well as a gas inlet arrangement in the chamber which is connected with a gas tank arrangement with at least one reactive gas. The plasma generating arrangement is described specifically as a low-voltage plasma generating arrangement: A cathode chamber communicates by way of a diaphragm with the process space. A hot cathode is mounted in the cathode chamber; an anode arrangement is present in the process space. Having a physically downward orientation, the workpiece carrier is arranged in an electrically insulated manner.

The principle of this low-voltage plasma generating arrangement is far preferred for the processes described herein over also known other plasma generating processes (such as microwave plasma), because it is capable of obtaining the above-mentioned energy characteristics in a preferred manner.

Thus, on the one hand, the present invention is based on processes and a system of this type; on the other hand, among others, the process described in International Patent Document WO98/58099 is to be implemented also according the present application, although—as will be explained in the following—while meeting additional criteria according to the object of the present invention.

The reason is that it is an object of the present invention to provide a process and a system of the above-mentioned type whose industrial suitability is significantly increased with respect to economic criteria, particularly with respect to higher up-times and higher troughput.

During the required high up-times, the high purity of the system has to be ensured for the above-mentioned processes. In addition, an optimal integrability of the process steps on the one hand, and of the system, on the other hand/or automated production should be achieved.

With respect to the process of the initially mentioned type, this object is achieved in that the process atmosphere during the plasma-enhanced treatment step is separated from the interior wall of a vacuum recipient exposed to the environment. The basic recognition is in this case that a functional separation, on the one hand, of structures which ensure the required vacuum-related pressure condition with respect to the ambient pressure and, on the other hand, of structures which are directly exposed to the treatment process will achieve the above-mentioned object.

According to International Patent Document WO98/58099, the interior surface of the vacuum chamber, normally made of stainless steel or Inox, is exposed directly to the process atmosphere. During the plasma-enhanced treatment step, specifically during the coating of workpiece or part by means of the low-energy plasma discharge, the vacuum chamber wall and thus the interior surface will heat up. Because of various effects, such as the absorption behavior of the interior surface during the preceding process exposures, if used in industrial manufacturing, this results in an intolerable contamination of the treatment step process atmosphere or in the formation of intolerable partial background gas pressures. Background gas in a process atmosphere in this case are those gas fractions which originate neither from the plasma discharge working gas, such as argon, nor from the admitted reactive gas or reactive gas mixture, nor from their gaseous reaction products. As a result of the approach according to the invention, it will now be possible to minimize the influence upon the process by the vacuum recipient wall.

The process according to the invention is used in a preferred manner (a) for coating the part or (b) for changing the material composition of the part to a defined penetration depth, or (c) for etching the surface of the part, particularly for etching of structure. In all mentioned cases, it is absolutely necessary to maintain process conditions required for the growth of epitaxial layers, within the scope of the production processes endeavored according to the invention. As a result of the change of the material composition according to the invention mentioned in (b), this addresses the implantation of material into a given target material.

Furthermore, a cleaning step suggested as a plasma-enhanced treatment step carried out according to the invention, or a cleaning step is suggested in addition to a plasma-enhanced treatment step according to the invention.

In a preferred embodiment of the process of the invention, a virtual substrate is produced. A virtual substrate is a semiconductor wafer which, in contrast to a wafer consisting of a generally monocrystalline semiconductor material, has a special layer construction but functionally is also used as a starting material for semiconductor devices.

A semiconductor material “A”, for example, monocrystalline silicon in the form of a wafer, is used as the starting substrate. A buffer layer is applied thereto which consists of preferably continuously changing fractions of semiconductor “A” and another semiconductor “B”, the progression normally being from a high “A” fraction and little “B” to a high “B” fraction and little “A”. This is called a “graded buffer layer”. The structure of this buffer layer is full of defects. On the buffer layer, a cover layer is grown which has a composition corresponding essentially to that of the uppermost buffer layer zone. The purpose is the achieving of a low-defect, no-dislocation mixed crystalline layer. These three components—the base or substrate, the buffer layer and the cover layer form the virtual substrate. As known to a person skilled in the art, the application of additional intermediate layers is also conceivable. The actual useful layer is applied to the virtual substrate and has the composition required for the characteristics of the semiconductor material to be achieved. A mixture of two semiconductors can again be used as the useful layer material, but also a layer consisting of a pure semiconductor, for instance “B”. As a rule, this layer is so thin that no dislocations will occur on it but the stress in this layer is maintained (band gap engineering). The epitaxial growth of this useful layer can be combined with the construction of the virtual substrate. However, prefabricated virtual substrates can also be subsequently provided with the useful layer.

The base or the mentioned substrate is first subjected to a plasma-enhanced cleaning, in contrast to previous processes, in which wet cleanings were used within the scope of the production of virtual substrates. Then, the hetero-epitaxial buffer layer is deposited as well as, if required, the above-mentioned cover layer. Optionally, according to the invention, the active layer, which is to be used, is also deposited then, or, after the depositing of the buffer layer, changing over into the cover layer, the actually finished virtual substrate, is made available for a deposition of the active layer which will take place later.

It should be pointed out here that, within the framework of known production processes for virtual substrates (including MBE—molecular beam epitaxy, UHVCVD—ultra high vacuum CVD, ALD—atomic layer deposition, among others), the replacement of the wet-chemical cleaning steps by a plasma-enhanced cleaning step in low-energy plasma by itself is also considered to be inventive and results in significant production-related advantages.

In the course of the addressed industrial manufacturing, it is generally often necessary to subject the parts which subsequently are to be treated by the above-mentioned plasma-enhanced treatment steps (a), (b), (c) first to a cleaning, for example, with respect to ambient-atmosphere-caused surface contaminations.

Furthermore, after each of the above-mentioned plasma treatment steps (a), (b), (c), a cleaning step may be required, for example, for cleaning contamination materials or gases released during the etching.

In an embodiment of the cleaning process, reactive gases (hydrogen, hydrogen—noble gas mixtures) can be used which may impair the materials used for encapsulating the process atmosphere.

It is therefore suggested to provide for such cleaning steps either a relatively low-cost metallic encapsulation, or to bound the cleaning process atmosphere directly by the interior wall of the vacuum recipient exposed to the environment.

The reason is that, for the above-mentioned treatment steps (a), (b), (c) of the parts, as will be explained in the following, non-metallic boundaries of the process atmosphere are considerably preferable; that is, materials which are inert with respect to the used plasma-activated reactive gases. However, in this cleaning step, it must also be ensured that the cleaned surfaces of the part are accessible to the subsequent treatment in an unimpaired manner just as if this treatment were the depositing of epitaxial layers. Thus, also in the case of the plasma-chemical cleaning step of the part, the above-mentioned low-energy plasma with the specified ion energy is used on the surface of the part.

Furthermore, are introduced and removed it is suggested that, in the considered process space, parts which successively, that is, in a serial time sequence, are subjected to at least one of the above-mentioned plasma-enhanced treatment steps and, after the implementation of a defined number of such treatment steps, another plasma-enhanced treatment step takes place in the above-mentioned process space, specifically a process space cleaning step, without a part being introduced into the process space or a substrate dummy being used. This process space cleaning step is preferably implemented in at least two partial steps: First the etching; then the cleaning of etching residues; the latter preferably in a plasma containing hydrogen, noble gas or a mixture thereof.

In view of the object of the invention, particularly in view of the implementation for high up-times, a considered process space is therefore cleaned in a plasma-enhanced manner, after a defined number of treatment steps have taken place. In a process space, parts are normally machined or cleaned either according to one of three methods. However, a case may also occur in which, in a single considered process space, in a programmed sequence, sequentially, in a coated or etched manner, a change of the material composition or, then according to Claim 3, a cleaning of the part is carried out.

The process atmosphere separation provided according to the invention from the vacuum recipient wall permits the subjecting of the process space or of the part to a plasma-chemical cleaning, using reactive gases to which the vacuum chamber wall must not be exposed. The fact that a considered process space, after a defined or definable number of treatment steps of parts can be subjected to a plasma-enhanced self-cleaning and then is immediately available again for the treatment of parts, drastically increases the up-time for the continuous operation. This is compared, for example, with the case that the process space is to be cleaned according to International Patent Document WO98/58099.

Summarizing the previous statements, it is therefore demonstrated that, by means of the production process according to the invention, with respect to quality demands to be made on epitaxy, a coating, a changing of the material composition of the part, an etching of structures on the part or its cleaning can be carried out while avoiding wet-chemical cleaning steps, and in that, between such treatment steps, a self-cleaning of the process space can be carried out, only by changing process parameters, particularly of the admitted reactive gases. The same process can also take place for cleaning the parts in the course of their production according to the invention in that the separation of the process atmosphere and the vacuum recipient is changed or omitted.

The part is preferably subjected in a locally separated manner to at least two of the above-mentioned plasma-enhanced treatment steps and the transport in-between takes place in a vacuum. According to Claim 8, this preferably takes place in a linear movement from one treatment step to the next, in the manner of a linear system or along a circular path, in the manner of a circular system known by the name of “cluster system”. There, treatment stations grouped around a circular transport in a programmed, optionally freely programmable manner are served with parts or workpieces by the circular transport.

In a preferred embodiment of the process according to the invention, the separation between the process atmosphere and the vacuum recipient wall surface takes place by limiting the process space by means of a surface which, in the original condition, is chemically inert with respect to the plasma-activated reactive gas or reactive gas mixture, preferably by means of a dielectric or graphitic surface.

During the operation, thus particularly during the coating (a), the changing of the material composition (b), or the etching (c), particularly the etching of the structure, or also the cleaning, material is deposited on this surface. However, this material is not or only tolerably process-contaminating. Specifically when, in the same considered process space, identical treatment steps are carried out on parts occurring in series, it is even desirable to coat the preferably dielectric or graphitic separating surface which, as mentioned above, is inert in the new condition, with the above-mentioned reaction product materials, however, only to the extent that the resulting coating also adheres in a secured manner to the above-mentioned surface.

The providing of the required inert, preferably dielectric surface can take place such that a structure forming an inert, preferably dielectric surface, is applied directly to the interior surface of the vacuum recipient, whether as a coating with such a material, or by the mounting of self-supporting wall parts with such an inward-facing surface directly to the interior vacuum recipient wall.

In a preferred embodiment, however, the inert surface is spaced away by an intermediate space at least along predominant surface sections from the interior wall of the vacuum recipient. This approach has significant advantages under the aspect of the exchangeability of a separating wall structure also with respect to being servicing-friendly, and under the aspect of a targeted defining of the surface temperatures.

The process space and the above-mentioned intermediate space can be pumped identically or differently. Among other things, this may permit the implementation of an atmosphere in the intermediate space which results in desired thermal conduction ratios between the vacuum recipient wall and the above-mentioned surface. If, in this case, a gas of a high thermal conduction capacity, such as helium, is admitted to this intermediate space, and/or, at least temporarily, a higher pressure than in the process space is implemented in this intermediate space, the heat conduction in this intermediate space is increased with respect to that in the process space, which may make it possible to keep the surface at the desired temperatures. It should be remembered, that below a defined vacuum pressure, the thermal conduction decreases with the pressure and is naturally a function of the thermal capacity of the concerned contained gas.

It should be stressed that when the surface made of an inert, preferably dielectric material is mentioned, this first addresses only the surface material of the surface facing the process space. This surface is preferably formed by that of a separating wall. This surface may be coated; thus, may have a metallic construction facing, for example, the vacuum recipient, with an inert surface facing the process space or the process atmosphere. In this sense, according to Claim 12, the surface can therefore be formed by a layer structure, permitting also the use of diamond-like materials or of diamond.

It is known that, in plasma-chemical processes, the coating rate always increases with a rising temperature (and the acted-upon plasma intensity). As mentioned above, it may be highly desirable to coat the surface facing the process space with reaction products of the plasma-activated reactive gas corresponding to the respective process. However, in this case, considerable attention must be paid to avoiding any peeling-off of the such a coating. These recognitions can be implemented such that, by controlling the temperature of the above-mentioned surface, during the implementation of the plasma-enhanced treatment step, a coating rate of the above-mentioned surface is minimized. This results, for example, in the possibility of selecting this interference coating rate to be significantly smaller than the effective rate on the part, and thus to subject the process space to the self-cleaning only after a relatively large number of completed treatments of parts. There, the above-mentioned coating will be removed before its thickness has reached a critical value, for example, with respect to a peeling-off.

In this case, the effective rate on the part, depending on the treatment, is the coating rate, the penetration rate, the etching rate, the cleaning rate.

It is also within the scope of the object to be achieved according to the invention to pay considerable attention to the degree of automation of the process and the system. It is therefore suggested that a feeding opening for the part be provided in the above-mentioned surface, and that the feeding opening for the treatment of the part be closed by the part and/or by a carrier for the part, at least to such an extent that the floor of charge carriers from the process space is prevented.

As another preferred embodiment, the low-energy plasma discharge is used with an electron source with an electron energy of <100 eV, preferably <50 eV, particularly preferably implemented with a DC discharge; in this case, preferably according to Claim 15, by means of a thermionic cathode, preferably a directly heated thermionic cathode. In a particularly preferred manner, the treated surface of the part is also exposed directly to the plasma.

Also preferably, at least two locally displaced anodes are also provided in the process space for the plasma discharge. These anodes are preferably each separately heatable. By the control of the electric potentials applied thereto and/or their temperature, the plasma density distribution in the process space can be adjusted and controlled dynamically and/or statically. A static adjustment is an adjustment which is set and is kept stationary at least during one treatment step. A dynamic adjustment is the fact that during the treatment step at least one of the above-parameters is changed with respect to the time, whether in the sense of a sweep, periodically, or aperiodically corresponding to defined curve shape in an oscillating manner, or in the form of an arbitrary linear or non-linear ramp function, during the treatment step. Particularly by means of the latter approach, it is possible to take into account the conditions which change during a process step in the process space and act upon these in a compensating manner or also achieve a desired time variation of the plasma density on the surface of the part.

Furthermore, a magnetic field is preferably generated in the process space, which magnetic field, analogous to the above-mentioned parameters anode potential and/or anode temperature, stationarily or dynamically, sets or controls the plasma density distribution on the surface of the part. As a result of the controlled time variation of the magnetic field, the plasma density distribution along the surface of the part can be changed, particularly preferably as if the part were to move periodically in a stationarily distributed plasma. Because of such a sweep of the magnetic field and the oscillating change of the plasma density along the surface of the stationarily held part, the same effect is achieved as if the part were to be moved in an oscillating or rotating manner, but particularly advantageously with respect to the vacuum, without moving parts.

As a result of the fact that the reactive gas is admitted to the process atmosphere in a distributed manner, preferably with an inflow direction essentially parallel to the part surface, and further preferably, with nozzling-in points which are equidistant from the part surface, an optimal exposure of the surface of the part is achieved to the plasma-activated reactive gas, and an optimal utilization of admitted fresh reactive gas, in the sense of an inverse operating ratio, specifically of the quotient of fresh reactive gas admitted per time unit to still fresh reactive gas pumped out per time unit.

For achieving effects as a result of the above-mentioned treatment steps, particularly according to (a), (b), (c) or the cleaning of the part according to Claim 3, of a quality required for depositing epitaxial layers, the partial pressure of background gases, as defined above, is kept at no more than 10⁻⁸, preferably at maximally 10⁻⁹, according to Claim 19.

The above-mentioned at least one plasma-enhanced treatment step of the process according to the invention, in a preferred first embodiment, is the depositing of a homo- or hetero-epitaxial layer. Also preferably, such a layer is deposited as a silicon germanium layer.

Also an essentially disk-shaped part is produced as the part.

As a further preferred embodiment, the part subjected to the treatment is a silicon wafer or a wafer consisting of a compound semiconductor, preferably of gallium arsenide, indium phosphide, silicon carbide or of glass.

In an extremely important embodiment of the production process of the invention virtual substrates of the above-mentioned type are produced which preferably contain silicon germanium.

In another preferred embodiment of the production process of the invention, parts, particularly the above-mentioned essentially flat or disk-shaped parts, are produced with diameters of at least 150 mm, preferably of at least 200 mm, preferably even of at least 300 mm.

In another preferred embodiment of the production process of the invention according to Claim 27, the coating of parts is implemented at a coating rate of at least 60 nm/min.

In connection with virtual substrates, particularly on a silicon germanium base, normally wet-chemical cleaning processes are used nowadays, whether for cleaning the surface of a finished virtual substrate for additional treatment steps, or for cleaning the surface of an already epitaxially coated substrate for the subsequent preparation of a virtual substrate, whether for cleaning the substrate suitable for epitaxial growth before epitaxially growing the buffer layer. Within the scope of the present invention, it was now recognized that, as a result of the use of the above-mentioned low-energy plasma for a plasma-enhanced cleaning step, the cleaning is implemented such that the subsequent implementation of the production of virtual substrates or of the production of components based on virtual substrates, can take place without any problems. This, that is, the bypassing of wet-chemical cleaning processes by the use of a plasma-enhanced cleaning process, always results in an important advantage and, in addition, this recognition permits the integration of such a plasma-enhanced cleaning into the production process of virtual substrates and of components based thereon. A process for producing a virtual substrate or a component on the base of a virtual substrate, preferably on a silicon germanium base, is therefore suggested which comprises at least one cleaning step which is plasma-enhanced and in which the workpiece is exposed to reactive gas or a reactive gas mixture admitted to a process space. This is activated by means of a low-energy plasma discharge with ion energy at the surface of the part of maximally 15 eV.

The surprising success which the inventors achieved by means of this dry cleaning process in connection with extremely difficult surfaces is attributed to the use of the low-energy plasma, as defined.

A vacuum treatment system according to the invention is specified which is particularly suitable for carrying out the process according to one of the above-mentioned aspects: The interior wall surface of the process chamber in the new condition is implemented of a material, preferably of a dielectric material, which is inert with respect to the plasma-activated reactive gas or reactive gas mixture; according to Claim 30, the process chamber comprising the process space is set off toward the inside from the vacuum chamber wall, that is, is implemented at a distance.

Other objects, advantages and novel features of the present invention will become apparent from the following detailed description of the invention when considered in conjunction with the accompanying drawings.

### BRIEF DESCRIPTION OF THE DRAWINGS

The invention will now be explained by means of figures.

FIG. 1 is a schematic view of a first embodiment of a process module according to the invention for carrying out the process according to the invention;

FIG. 2 is a representation analogous to that of FIG. 1 of a preferred embodiment of the process module according to FIG. 1 for carrying out the process according to the invention;

FIG. 3 is a representation analogous to FIGS. 1 and 2 of another process module type according to the invention for carrying out processes according to the invention, specifically the cleaning according to the invention;

FIG. 4 is a representation analogous to FIGS. 1 to 3 of a modification of the process module illustrated in FIG. 3 for implementing the process according to the invention, specification the cleaning according to the invention;

FIG. 5 is a simplified view of a preferred embodiment of a process module of the invention according to FIG. 2 which can be changed into a process module according to FIG. 3 or 4 for carrying out the process according to the invention;

FIG. 6, with respect to a diaphragm axis A of the process module according to FIG. 5, is a view of the local and time-related modulation, caused by the control, of magnetic field components parallel to the axis A, above a plane E, perpendicular to the diaphragm axis A;

FIG. 7 is a schematic view of the passage coating of a process module according to one of FIGS. 1 to 5 with workpieces and, above the time axis, its self-cleaning after a defined number of implemented treatment steps or as required;

FIG. 8 is a view of the combination of process modules according to FIGS. 1 to 5 in an inline passage system; and

FIG. 9 is a simplified top view of the combination of process modules according to FIGS. 1 to 5 for forming a circular or cluster system, particularly for the production according to the invention of virtual substrates and of components on a base of virtual substrates.

FIG. 1 is a schematic view of a process module Type I according to the invention. A chamber wall 1 of a vacuum recipient 3 encloses a process space PR, wherein a plasma is generated. In the process space PR, a substrate carrier 5 is provided, and a feeding line 7 communicates, on the one hand, with the process space PR and, on the other hand, with a reactive gas tank arrangement 9. By way of a pump connection 11, as schematically illustrated by means of the vacuum pump 13, the process space PR is pumped down to the pressure of maximally 10⁻⁸ mbar, preferably maximally 10⁻⁹ mbar, required for carrying out the production process according to the invention. The construction of the recipient meets UHV requirements (for example, metallically sealed vacuum tank, bakeable). The by far predominant surface area of the surface of the chamber wall 1 facing the process space PR, which normally consists of stainless steel or Inox, is produced of a material which is inert with respect to the plasma-activated reactive gas in tank 9. According to the embodiment of the Type I process module illustrated in FIG. 1, for this purpose, the chamber wall 1 is coated on the inside with the above-mentioned inert material, or, on the chamber wall 1 wall parts are mounted on the inside at least with interior surfaces made of the above-mentioned inert material. In FIG. 1, this coating or these inert material surfaces have the reference number 15. After the pumping-down of the process space PR to the above-mentioned required partial background gas pressure, while working gas, such as argon, is admitted, the low-energy plasma required according to the invention is generated in the process space PR, which plasma, in the area of the substrate carrier 5 or of a part deposited thereon, results in ion energies E of
0 eV<E<15 eV.
As the material of the surface 15 facing the process space PR, a dielectric material, preferably at least one of the materials indicated in the following Group G is used:

Quartz, graphite, silicon carbide, silicon nitride, aluminum oxide, titanium oxide, tantalum oxide, niobium oxide, zirconium oxide, diamond-like carbon or diamond, the latter surface materials being used as coating materials.

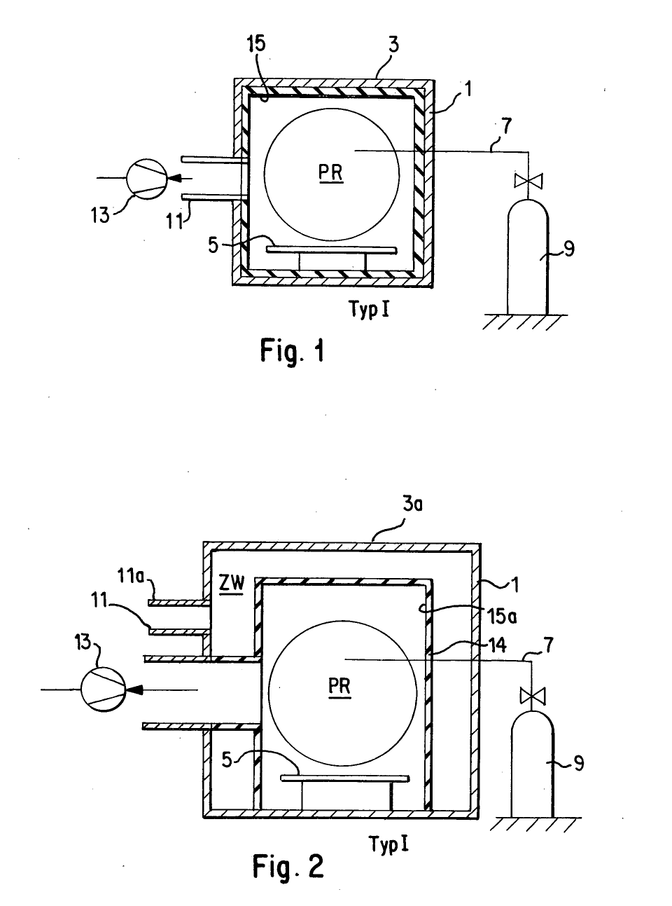

In a representation analogous to that of FIG. 1, FIG. 2 schematically shows a preferred embodiment of the Type I process module according to FIG. 1 of the invention. For the parts already described in FIG. 1, the same reference numbers are used in FIG. 2. In contrast to the embodiment according to FIG. 1, in the embodiment of FIG. 2, the process space PR is bounded by a process space wall 14 spaced away along predominant sections of the chamber wall 1, also preferably made of stainless steel or Inox. At least the surface 15a of the process space wall 14 facing the process space PR consists of the material, preferably of a dielectric material, which is inert with respect to plasma-activated reactive gas in the tank arrangement 9. This material is again particularly preferably at least one of the above-mentioned materials of Group G.

The wall 14, which actually forms a process space casing within the vacuum chamber together with the wall 1, may consist of the material forming the surface 15a, or the inert material forming the surface 15a is built up, for example, stacked up in layers, on a carrying wall (not shown) which faces the wall 1, which carrying wall, because it is not exposed to the process space PR, can then be constructed, for example, of stainless steel or Inox. By means of the pump connection 11 and the pump 13, the process space PR is pumped down to the partial background gas pressure explained in conjunction with FIG. 1 while, for example, and as illustrated in FIG. 2, the intermediate space ZW between the vacuum chamber wall 1 and the casing 14 is pumped down by way of a separate pump connection 11a by the same or by another vacuum pump.

A person skilled in the art will easily recognize that, also when the same pump 13 is used for pumping down both spaces, specifically the process space PR and the intermediate space ZW, corresponding controllable throttling elements are installed in the assigned pump connection pieces 11 and 11a. With respect to the low-energy plasma, which is used for carrying out the process according to the invention on the module according to FIG. 2, the prerequisites apply which were established in conjunction with the module explained in FIG. 1. The process space casing provided in the embodiment of FIG. 2 and formed by the wall 14 is preferably designed to be exchangeable in the recipient 3a.

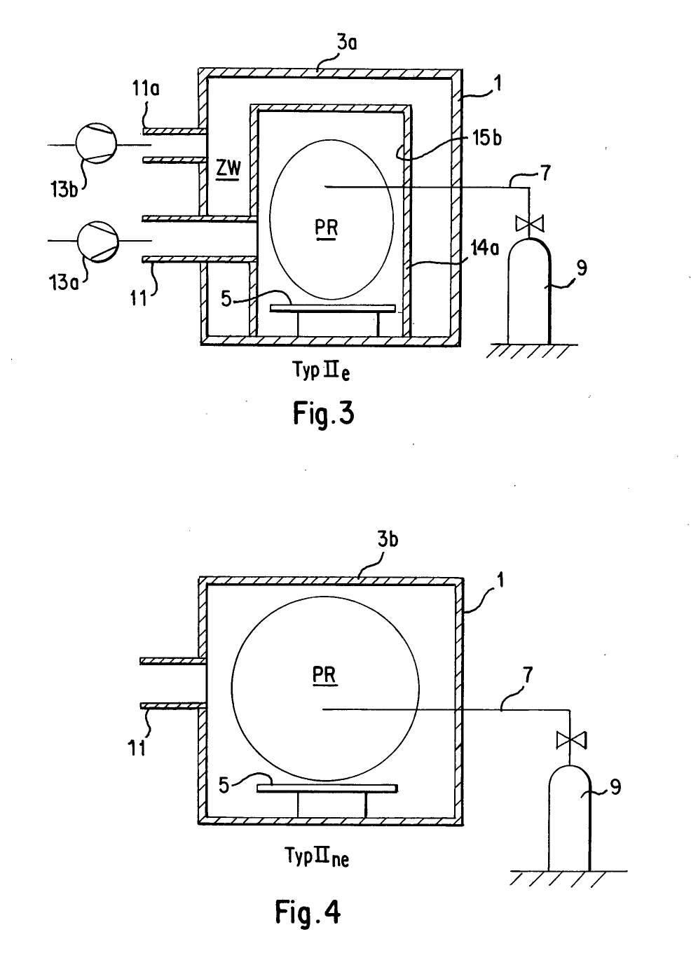

Analogous to the representations of FIGS. 1 and 2, FIG. 3 shows a process module of the Type IIₑ which, compared with that illustrated in FIG. 2, differs only in that the surface 15b enclosing the process space PR does not meet the inertness requirements explained in conjunction with the process module according to FIG. 2, and in the case of which the wall 14a, for example, like the wall 1, is produced of stainless steel or Inox or another metal. With respect set partial background gas pressures, ion energies in the substrate carrier range, the explanations apply which were made concerning FIGS. 1 and 2. The normally metallic wall 14a is also exchangeable, so that the process module Type IIₑ according to FIG. 3 can easily be changed into a process module Type I according to FIG. 2 and vice versa.

Irrespective of the processes implemented thereon, the process module structures according to FIGS. 1 to 3 correspond to the invention.

In a representation analogous to FIGS. 1 to 3, FIG. 4 shows another process module Type IIₙₑ which does not correspond to the invention. In contrast to the process modules explained by means of FIGS. 1 to 3, in the case of Type IIₙₑ, the process space is bounded by the process chamber wall 1 with a surface which consists, for example, of stainless steel or Inox. If this process module, whose structure does not correspond to the invention, is, however, used according to the invention, that is, a process according to the invention is carried out by means of this process module, or such a module is used within the scope of a process according to the invention, the data indicated for Type I and Type IIₑ modules apply with respect to the set partial background gas pressure and the plasma.

It is clearly demonstrated that the Type I, Type IIₑ and Type IIₙₑ modules can be converted to one another by the corresponding removal or installation of the corresponding process space casing 14, 15b.

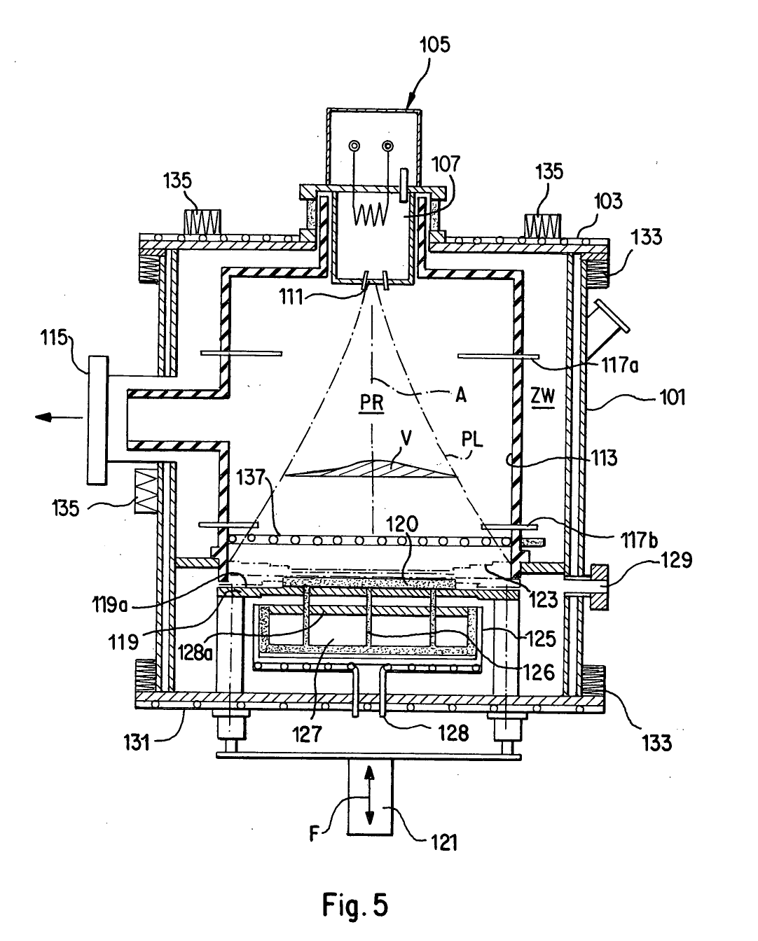

FIG. 5 illustrates a preferred embodiment of the Type I process module according to FIG. 2. In this case, it should be pointed out that all measures originating from the module according to FIG. 2 preferably used additionally or specifically on the module according to FIG. 5 can be used on the principal module according to FIG. 2 individually or in arbitrary partial combinations.

As will be demonstrated, in a preferred embodiment, the Type I process module illustrated in FIG. 5 can easily be converted to a Type IIₑ module or to a Type IIₙₑ module. The recipient wall 101 of the process module according to FIG. 5, preferably made of stainless steel or Inox, centrally, preferably on its upper frontal plate 103, carries an electron source 105 for co-generating the plasma discharge in the process space PR. Although, within the scope of the ion energies required in principle according to the invention, in the substrate carrier area, other plasmas, such a microwave plasmas can also be used, an electron source, such as electron source 105, is preferably used, which emits electrons with an electron energy of maximally 100 eV, preferably of maximally 50 eV. In a preferred embodiment, the plasma discharge is implemented as a DC discharge. The electron source 105 according to FIG. 5 is preferably constructed with a thermionic cathode, preferably a directly heated thermionic cathode 107, installed in a cathode chamber 109 with a cathode chamber wall electronically insulated from the recipient wall 101, 103. The cathode chamber communicates by way of a diaphragm 111 with the process space PR. The working gas, such as argon, is preferably (not shown) admitted into the cathode chamber 109, among other things, in order to protect the thermionic cathode 107 from influences of the reactive gas in the process space PR and permit a higher electron emission.

Spaced away from the recipient wall 103, 101 and setting up the intermediate space ZW together with it, the process space casing 113 enclosing the process space PR, analogous to FIG. 2, is preferably mounted in an exchangeable manner. The process space PR within the casing 113 as well as the intermediate space ZW are pumped here by way of the same pump connection 115, in which case optionally different pump cross-sections lead from this connection 115, on the one hand, to the intermediate space ZW, and, on the other hand, to the process space PR.

An anode arrangement acts within the process space PR. As illustrated in FIG. 5, this anode arrangement is preferably formed by two or more anodes 117a and 117b arranged concentrically with respect to the diaphragm axis A. They can be conducted (not shown), in each case, independently of one another, to ground potential or to electric anode potentials which, also preferably, can be adjusted independently of one another. Also preferably, the metallic recipient wall 101, 103 is applied to a reference potential, preferably ground potential. The anodes 117a, 117b displaced along the diaphragm axis A, in addition to being electrically operable independently of one another, preferably (not shown) are also heatable and coolable independently of one another. This is implemented in that temperature adjusting medium lines extend in these anodes and/or helical heating filaments are installed.

In FIG. 5, the plasma beam PL, which is generated by the preferably used plasma generating arrangement, is illustrated in FIG. 5 in a dash-dotted manner, with a plasma density distribution indicated at V in a purely heuristic manner, coaxial to the axis A of the diaphragm. As a result of a corresponding action upon the anodes 117a and 117 by anodic potential and a controlled tempering of these anodes, the plasma density distribution V can be adjusted in a targeted manner.

In the process space PR, a wafer holder 119 is mounted or—as will be explained in the following—can be introduced into the process space PR in a controlled manner. Although it is definitely possible to provide the substrate holder 119, for the preferred treatment of disk-shaped workpieces 120, defining a carrier surface 119a, with this carrier surface 119a parallel to the diaphragm axis A, at an oblique angle thereto or perpendicular thereto—according to FIG. 5—, but eccentrically, the wafer holder 119 is arranged by means of its carrier surface 119 very preferably concentrically to the axis A of the diaphragm 111. By means of an external drive 121, the wafer holder 119, as illustrated by means of the double arrow F, can be moved toward the receiving opening 123 defined by the process space casing 113 and can be moved back from the receiving opening 123. When the wafer holder 119 is moved up by means of the drive 121 completely against the process space PR, its edge part 125 closes off the clear opening 123 of the process casing 113 at least such that charge carriers are prevented from exiting the process space PR.

A workpiece or part to be treated which, as mentioned above, is preferably disk-shaped, is placed through a slotted valve 129 on stationary receiving supports 126, while the wafer or workpiece holder 119 is lowered. Subsequently, the wafer holder 119 is lifted, reaches by means of its carrier surface 119a under the workpiece or the wafer 120, lifts it off the stationary support 126, and moves it upward into the process space PR, while, when the machining position is reached closing off by means of its edge surface 125 the process space to the above-mentioned extent.

The supports 126 are mounted on a workpiece temperature adjusting device 127 which is acted upon by temperature adjusting medium by way temperature adjusting medium feeding and removal lines 128. Normally, the introduced substrate 120 is heated by way of the plate 128a. The wafer holder 119 is illustrated in FIG. 5 by a broken line in its processing position.

The recipient wall 101 and its face-side end plates 103 and 131 are temperature adjusted, preferably cooled. For this purpose, the wall 101 forming the casing is constructed as a double wall, with a temperature adjusting medium system installed in-between. Likewise, temperature adjusting medium line systems are installed into the front plates 103 and 131.

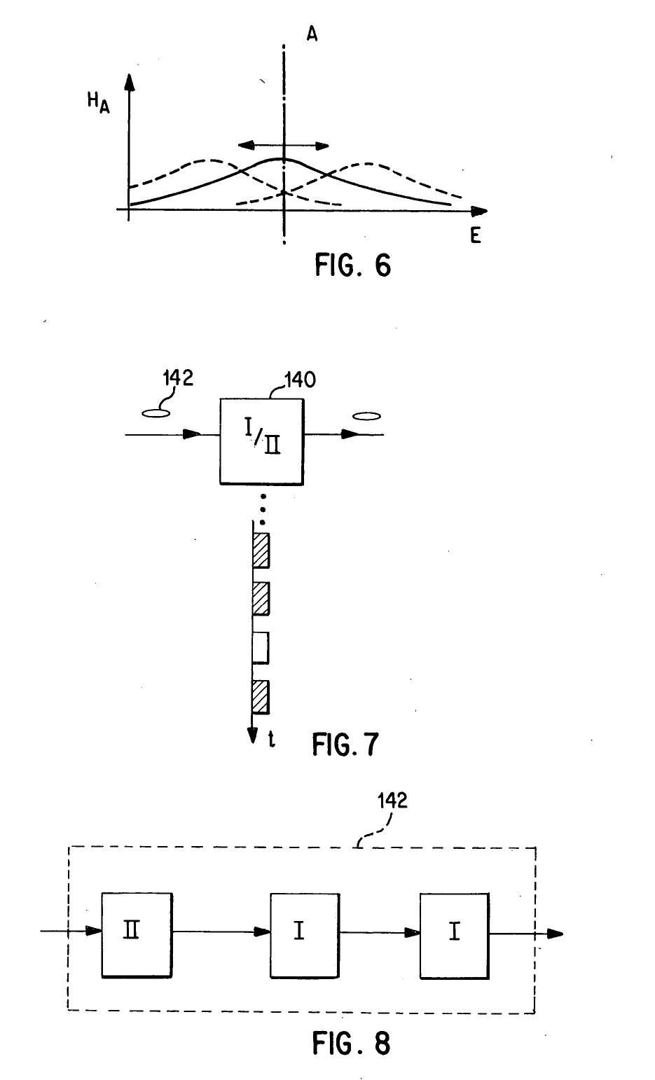

Helmholtz coils 133 as well as distributed deflection coils 135 are mounted outside the vacuum recipient. By means of the Helmholtz coils 133, a magnetic field pattern is generated in the process space PR which is essentially parallel and symmetrical to the axis A. By means of the deflection coils 135, this magnetic field pattern can be displaced in planes perpendicular to the axis A, as schematically illustrated in FIG. 6. As a result of this “displacement” of the magnetic field intensity distribution H_{A}, a “displacement” of the plasma density distribution V is obtained on a substrate applied to the substrate carrier 119. As a result, a relative movement is achieved between the plasma density distribution V and the workpiece surface on the substrate carrier 119 which is to be treated, as if the substrate were displaced with respect to the plasma with a time-constant plasma density distribution. As a result of this field distribution control, the same effect is obtained on the substrate as if this were mechanically moved with respect to the plasma but without any mechanical substrate movement.

Reactive gas is admitted by way of the reactive gas inlet 137 into the process space PR. As illustrated, the reactive gas inlet is preferably arranged coaxially to the axis A in the immediate area of the substrate 120 or the substrate carrier 119 situated in the processing position, with inlet openings essentially parallel to the substrate surface to be treated.

As mentioned above, the vacuum recipient 101, 103, which is preferably made of stainless steel, is cooled intensively. It meets UHV requirements. In this case, the intensive cooling prevents the heating-up of the steel during the process and thus a connected release of carbon-containing gases from the steel.

With respect to the material of the process space casing 113, particularly its surface exposed to the process, the statements made by means of FIG. 1 apply: The inert material, preferably a dielectric material and, as mentioned, preferably from Group G of materials, is stable at the high process temperatures and establishes no gaseous compounds with the used reactive gases, such as particularly hydrogen, silane, germane, borane, chlorine, NF₃, HCl, SiH₃CH₃, GeH₃CH₃, N₂, ClF₃, PH₃, AsH₄. Thus, it is achieved that there will be no contaminations of the part 120. disturbing coating of the interior surface of the process space casing 113 is critical only under the aspect of particle formation. A thin disturbing coating may even be preferred in order to ensure a still better purity of the process which is than surrounded virtually only by process-inherent material.

In the case of process modules Type I, the vacuum chamber wall, usually made of stainless steel, is not coated because it is protected from the reactive gases and the plasma by the process space casing 113; also, because, as illustrated in FIG. 5, the intensive cooling additionally considerably reduces a precipitation from the gaseous phase there. The statements made with respect to the interior surface of the process space casing 113 also apply to the surfaces of the substrate holder 119 exposed to the process.

The process space casing 113 is preferably constructed in several parts (not shown), so that it can be removed or exchanged without demounting the anode arrangement 117a, 117b. By the removal of the process space casing 113 illustrated in FIG. 5, a preferred embodiment of the Type IIₙₑ process module is implemented, and by replacing the process space casing 113 by a similarly shaped casing made of metal, a Type IIₑ process module according to FIG. 3 is implemented.

The following is a compilation of the processes carried out in each case by means of the process modules introduced by means of FIGS. 1 to 5.

Type I

While meeting quality requirements existing when coating parts by means of an epitaxial layer, this process module is used for carrying out reactive coatings in a plasma-enhanced manner, or plasma-enhanced reactive etching, or plasma-enhanced reactive altering processes ranging from the material composition on the workpiece to defined penetration depths; or, particularly combined with the above-mentioned process steps according to the invention, the surfaces of the workpieces or parts are subjected to a plasma-enhanced reactive cleaning, particularly in hydrogen plasma. After passing through a defined number of the above-mentioned treatment steps or as required, these Type I process modules are subjected to a self-cleaning without introducing a workpiece part or using a substrate dummy. This self-cleaning comprises preferably, on the one hand, a plasma-enhanced reactive etching step; on the other hand, a subsequent plasma-enhanced reactive cleaning step for etching residues, preferably carried out in a hydrogen plasma.

Type II

The Type II process modules are used for cleaning workpieces in a more penetrating manner, as required, for example, when they are supplied to the above-mentioned treatment steps, which meet epitaxial quality requirements, from the ambient atmosphere. Also in these Type II process modules, in combination with the treatment processes meeting the above-mentioned highest quality demands, the parts are cleaned by means of the above-mentioned low-energy plasma, in a reactive manner, preferably first by a plasma-enhanced reactive etching, then by a plasma-enhanced reactive cleaning, preferably in hydrogen plasma.

With respect to preferred coating processes, specifically for the depositing of hetero- or homo-epitaxial layers by means of the Type I modules, reference is made to the complete contents of the approach according to the initially mentioned International Patent Document WO98/58099.

FIG. 7 is a schematic view of a Type I or Type II process module 140. During the passage operation, parts 142 to be treated sequentially are supplied to the process module 140 and treated parts are removed from the module. On the time axis t illustrated in FIG. 7, only as an example, coating and/or etching and/or material altering and/or cleaning steps according to the invention on the parts 142 are illustrated in a hatched manner; in each case, followed, as required or after a defined number of such treatment steps, by a non-hatched self-cleaning step of the module 140 charged in the passage operation.

FIG. 8 schematically illustrates how, inside a vacuum atmosphere of a system 144, for example, an inline system, for example, workpieces are first subjected in a Type II process module to an initial cleaning and are then, in Type I process modules subjected to coating, etching, material altering and optionally also cleaning steps. Here also, analogous to the representations in FIG. 7, the provided process modules are subjected to a self-cleaning after a respective given number of processing cycles.

As mentioned initially, a preferred process of this type is the production of virtual substrates. Accordingly, in the Type II process module, the base, suitable for a subsequent hetero-epitaxial layer growth, is reactively cleaned in a plasma-enhanced manner, using a halogen, but preferably hydrogen, as the reactive gas. Subsequently, in one or several of the subsequent Type I process modules, the hetero-epitaxial layer is grown such that the lattice constant is changed and, by the successive graded building-in of another material, a surface structure is achieved which is as free of defects as possible. Then—in another Type I module—optionally the epitaxial growth of the semiconductor layer to be used is implemented in a definably mechanically strained manner for adjusting the band gap and setting the desired semiconductor characteristics, as, for example, the charge carrier mobility. Optionally, additional treatment steps according to the invention will follow until the finished virtual substrate is unloaded from the system 144.

A person skilled in the art is definitely familiar with the fact that, also during the production of the virtual substrate, additional layers can be built in, or that cleaning steps can be provided between the coating steps, preferably as “soft cleaning steps” in a Type I process module.

Although schematically, FIG. 8 illustrates an “inline” system, in which the workpiece transport from one module to the next takes place in a vacuum in an essentially linear manner.

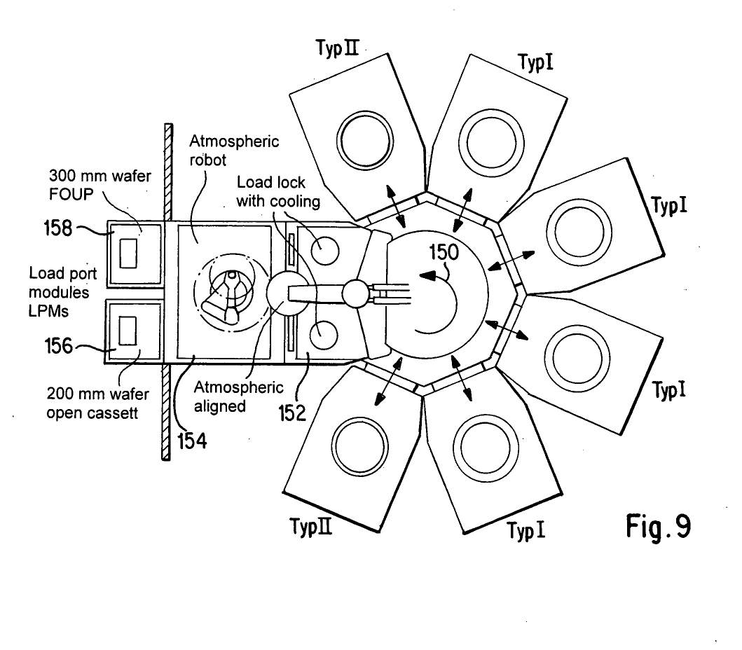

FIG. 9 is a schematic top view of the preferred arrangement of several Type I and Type II process modules as respective clusters for forming a cluster system. This comprises a circular vacuum transport chamber 150 which services the process modules essentially radially. Unprocessed substrates are loaded from a transfer chamber 152 and treated substrates are transferred therein, where the latter, for example, cool off. From the, for example, provided input and output transfer chamber 152, the substrates are removed by means of a robot unit 154 situated in the normal atmosphere, or are fed to the respective transfer chamber 152 from storage magazines 156 for untreated substrates and removed from the respective transfer chamber 152 to storage magazines 158 for treated finished substrates. With respect to its time sequences, the system is controlled by a program control system, for example, a freely programmable program control system.

The described process modules, which can all be converted into one another, can treat substrates which have a diameter of at least 150 mm, preferably of at least 200 mm, preferably even of at least 300 mm. In the case of the epitaxial coating by means of the processes described in the above-mentioned International Patent Document WO98/58099, which is enclosed as Attachment A with respect to the process disclosure of the present application, coating rates of at least 60 nm/min. are reached at the above-mentioned substrates.

1.-20. (canceled)

21. A vacuum treatment system, comprising:
at least one vacuum chamber with a wall, the exterior surface thereof being exposed to ambient said wall being construed to hold a pressure difference between a vacuum within said chamber and ambient pressure and further having at least one workpiece carrier;
a cathode chamber mounted to said vacuum chamber and communicating with the inside thereof via a diaphragm
a DC plasma discharge generating arrangement;
a gas tank arrangement containing at least one reactive gas or at least one reactive gas mixture and in flow communication with said vacuum chamber;
a processing compartment with a further wall within said vacuum chamber, containing said workpiece carrier in an operating position thereof and wherein said discharge is generated and further with which said gas tank arrangement is in flow communication, a surface of said further wall bordering said processing compartment within said vacuum chamber consisting, prior to processing in said component, of a dielectric material which is inert with respect to said reactive gas or said reactive gas mixture as activated by a plasma discharge generated by said DC arrangement; and
a magnetic field generating arrangement generating within said processing compartment a magnetic field,
wherein said processing compartment is bordered by an enclosure distant from an inner surface of said wall at least along predominant parts thereof and wherein said plasma generating arrangement generates a low energy plasma discharge with an ion energy E adjacent said workpiece carrier of
0 eV<E<15 eV.

22. A system according to claim 21, wherein an inner surface bordering said processing compartment consists of at least one of the materials of the group: Quartz, graphite, silicon carbide, silicon nitride, aluminum oxide, titanium oxide, tantalum oxide, niobium oxide, zirconium oxide or of a layered material, wherein at least a part of said layers consist of at least one material of said group, this group then including said diamond-like carbon and diamond.

23. The system of claim 21, wherein said plasma generating arrangement comprises an electron source emitting electrons with an electron energy of at most 100 eV.

24. The system of claim 23, wherein said electron source is selected to emit electrons with an electron energy of at most 50 eV.

25. The system of claim 21, wherein said plasma generating arrangement is a DC low voltage plasma generating arrangement.

26. The system of claim 21, wherein said plasma generating arrangement comprises a thermionic cathode.

27. The system of claim 26, wherein said thermionic cathode is a directly heated thermionic cathode.

28. The system of claim 21, wherein said cathode chamber is mounted to said vacuum chamber in an electrically isolated manner.

29. The system of claim 21, wherein a central axis of said diaphragm intersects with said workpiece carrier.

30. The system of claim 21, wherein said central axis intersects with said workpiece carrier at least approximately perpendicularly.

31. The system of claim 21, wherein said central axis intersects said workpiece carrier at least substantially in the center of said workpiece carrier.

32. The system of claim 31, wherein said metal is tantalum or Inkonell.

33. The system according to claim 21, further comprising within said processing compartment at least two mutually distant anodes which are operable on different electrical potentials.

34. The system of claim 33, wherein said anodes are individually heatable.

35. The system of claim 27, further comprising at least two anodes within said processing compartment, said anodes being staggered along a central axis of said diaphragm.

36. The system of claim 35, wherein said at least two anodes are arranged coaxially with respect to said central axis.

37. The system of claim 35, wherein said anodes are at least one of operable on different electric potentials and individually heatable.

38. The system of claim 21, wherein predominant parts of said wall are conceived as double-wall defining for an interspace, said interspace being connected to an inlet for a temperature-controlling medium.

39. The system of claim 38, wherein said interspace is connected to an inlet for a temperature-controlling liquid.

40. The system of claim 21, wherein said magnetic field generating arrangement is controllable.

41. The system of claim 21, wherein said magnetic field generating arrangement comprises Helmholtz coils.

42. The system of claim 41, wherein said Helmholtz coils are mounted outside said vacuum recipient.

43. The system of claim 21, wherein said workpiece carrier comprises a heating and/or cooling arrangement.

44. The system of claim 21, wherein said wall has a sealingly closable handling opening for a workpiece to be treated in said vacuum chamber.

45. The system of claim 21, wherein said vacuum chamber comprises a controllable closable workpiece handling opening, further comprising a second of said vacuum chambers, said handling openings of said one and said at least one further vacuum chambers being interconnected by means of a vacuum workpiece transport arrangement.

46. The system of claim 45, wherein said workpiece transport arrangement is one of a linear and of a rotary transport arrangement.

47. The system of claim 45, wherein in one of said vacuum chambers said processing compartment is bordered by a metallic inner surface of said wall.
